(19) United States
(12) Patent Application Publication
(10) Pub. No.: US 2015/0115773 A1
(43) Pub. Date: Apr. 30, 2015

(54) ULTRASOUND TRANSDUCER AND METHOD FOR MANUFACTURING AN ULTRASOUND TRANSDUCER

(71) Applicant: General Electric Company, Schenectady, NY (US)

(72) Inventors: XIANG LI, Niskayuna, NY (US); Ying Fan, Niskayuna, NY (US)

(73) Assignee: General Electric Company, Schenectady, NY (US)

(21) Appl. No.: 14/068,338

(22) Filed: Oct. 31, 2013

(51) Int. Cl. H01L 41/09; H01L 41/22

(52) U.S. Cl. CPC H01L 41/09; H01L 41/22
USPC 310/335; 310/334; 29/25.35

(57) ABSTRACT

An ultrasound transducer includes an acoustic layer that includes a micromachined piezoelectric composite body having a front side and an opposite back side. The micromachined piezoelectric composite body is configured to convert electrical signals into ultrasound waves to be transmitted from the front side toward a target. The micromachined piezoelectric composite body is configured to convert received ultrasound waves into electrical signals. A dematching layer is connected to the back side of the micromachined piezoelectric composite body of the acoustic layer. The dematching layer has a higher acoustic impedance than an acoustic impedance of the acoustic layer.

### BACKGROUND

Atherosclerosis is a systemic disease in which fatty deposits, inflammation, cells, and scar tissue build up within the arterial wall. Progression of plaques can cause lumen narrowing and intracoronary thrombosis, which may lead to relatively serious health problems such as heart attack, stroke, or even cardiac death.

Ultrasound imaging has become a valuable medical imaging modality for the diagnosis of atherosclerosis. Specifically, catheter and/or guide wire based intravascular ultrasound (IVUS) imaging techniques have been used to facilitate atherosclerosis diagnoses. But, known IVUS scanning devices may have insufficient resolution for imaging some symptoms of atherosclerosis. For example, the transducers of known IVUS scanning devices operate between approximately 20 and approximately 45 MHz in center frequency with a bandwidth between approximately 30% and approximately 50%, which may provide insufficient resolution for evaluating the vulnerability of plaques with relatively thin fiberous caps (e.g., less than approximately 64 μm).

### BRIEF DESCRIPTION

In an embodiment, an ultrasound transducer includes an acoustic layer that includes a micromachined piezoelectric composite body having a front side and an opposite back side. The micromachined piezoelectric composite body is configured to convert electrical signals into ultrasound waves to be transmitted from the front side toward a target. The micromachined piezoelectric composite body is configured to convert received ultrasound waves into electrical signals. A dematching layer is connected to the back side of the micromachined piezoelectric composite body of the acoustic layer. The dematching layer has a higher acoustic impedance than an acoustic impedance of the acoustic layer.

In an embodiment, a method is provided for manufacturing an ultrasound transducer. The method includes forming a micromachined piezoelectric composite body having a front side and an opposite back side. The micromachined piezoelectric composite body is configured to convert electrical signals into ultrasound waves to be transmitted from the front side toward a target. The micromachined piezoelectric composite body is configured to convert received ultrasound waves into electrical signals. The method also includes connecting a dematching layer to the back side of the micromachined piezoelectric composite body. The dematching layer has a higher acoustic impedance than an acoustic impedance of the micromachined piezoelectric composite body.

In an embodiment, an ultrasound transducer includes a lens and an acoustic layer, which includes a micromachined piezoelectric composite body having a front side and an opposite back side. The micromachined piezoelectric composite body is configured to convert electrical signals into ultrasound waves to be transmitted from the front side toward a target. The micromachined piezoelectric composite body is configured to convert received ultrasound waves into electrical signals. The lens is connected to the front side of the micromachined piezoelectric composite body of the acoustic layer. A dematching layer is connected to the back side of the micromachined piezoelectric composite body of the acoustic layer. The dematching layer has a higher acoustic impedance than an acoustic impedance of the acoustic layer. A backing layer is connected to the dematching layer such that the dematching layer is disposed between the backing layer and the acoustic layer.

### BRIEF DESCRIPTION OF THE DRAWINGS

FIG. 1 is a perspective view of an ultrasound transducer formed in accordance with various embodiments.

FIG. 2 is a cross-sectional view of the ultrasound transducer shown in FIG. 1.

FIG. 3 is a perspective view of an embodiment of a micromachined piezoelectric composite body of an embodiment of an acoustic layer of the ultrasound transducer shown in FIGS. 1 and 2.

FIG. 4 is a flowchart illustrating a method for manufacturing an ultrasound transducer in accordance with various embodiments.

FIG. 5 is a block diagram of an ultrasound system in which various embodiments may be implemented.

FIG. 6 is a diagram illustrating a three-dimensional (3D) capable miniaturized ultrasound system in which various embodiments may be implemented.

FIG. 7 is a diagram illustrating a 3D capable hand carried or pocket-sized ultrasound imaging system in which various embodiments may be implemented.

FIG. 8 is a diagram illustrating a 3D capable console type ultrasound imaging system in which various embodiments may be implemented.

### DETAILED DESCRIPTION

The foregoing summary, as well as the following detailed description of certain embodiments will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (e.g., processors or memories) may be implemented in a single piece of hardware (e.g., a general purpose signal processor or a block of random access memory, hard disk, or the like) or multiple pieces of hardware. Similarly, the programs may be stand alone programs, may be incorporated as subroutines in an operating system, may be functions in an installed software package, and/or the like. It should be understood that the various embodiments are not limited to the arrangements and instrumentality shown in the drawings.

As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional elements not having that property.

Various embodiments provide ultrasound transducers and methods for manufacturing ultrasound transducers. An ultrasound transducer in accordance with various embodiments includes an acoustic layer that includes a micromachined piezoelectric composite body having a front side and an opposite back side. The micromachined piezoelectric composite body is configured to convert electrical signals into ultrasound waves to be transmitted from the front side toward a target. The micromachined piezoelectric composite body is configured to convert received ultrasound waves into electrical signals. A dematching layer is connected to the back side of the micromachined piezoelectric composite body of the acoustic layer. The dematching layer has a higher acoustic impedance than an acoustic impedance of the acoustic layer.

A technical effect of at least some of the various embodiments described and/or illustrated herein is an ultrasound transducer (such as, but not limited to, a catheter and/or guide wire based intravascular ultrasound [IVUS] transducer) having an increased bandwidth, an increased sensitivity, and/or a reduced acoustic impedance as compared to at least some known ultrasound transducers, for example as compared to at least some known IVUS transducers. A technical effect of at least some of the various embodiments described and/or illustrated herein is an ultrasound transducer (such as, but not limited to, a catheter and/or guide wire based intravascular ultrasound [IVUS] transducer) that can provide relatively high definition tissue imaging with a relatively large dynamic range and relatively deep penetration depth. A technical effect of at least some of the various embodiments described and/or illustrated herein is an ultrasound transducer (such as, but not limited to, a catheter and/or guide wire based intravascular ultrasound [IVUS] transducer) having an improved imaging quality (such as, but not limited to, a greater resolution and/or the like) as compared to at least some known ultrasound transducers, for example as compared to at least some known IVUS transducers. The improved imaging quality provided by at least some of the various embodiments described and/or illustrated herein may be of value for evaluating various intravascular structures, procedures, conditions, symptoms, and/or the like, such as, but not limited to, lumen dimensions, plaque composition, stent implantation, and/or the like. For example, the improved imaging quality provided by at least some of the various embodiments described and/or illustrated herein may improve the accuracy of diagnosing atherosclerosis.

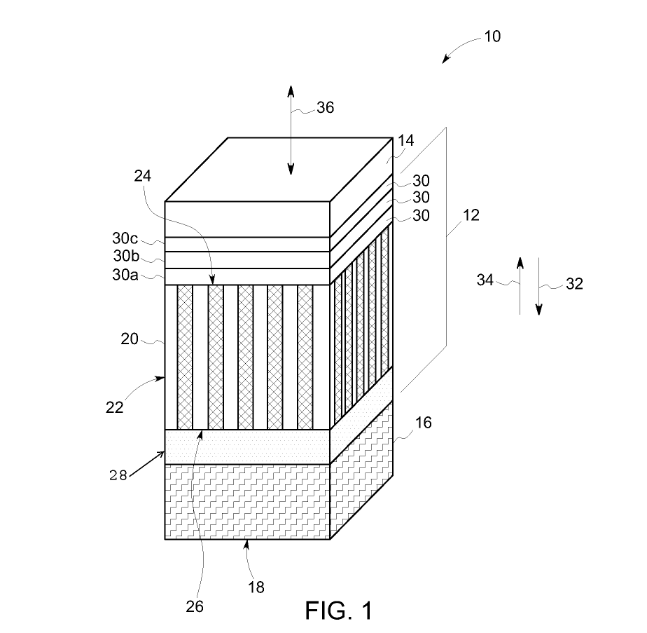

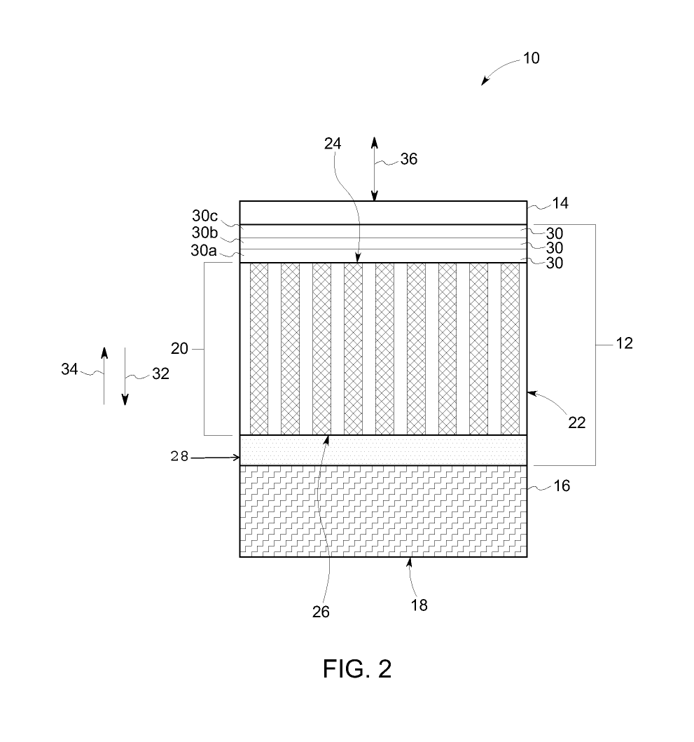

FIG. 1 is a perspective view of a portion of the ultrasound transducer 10 formed in accordance with various embodiments. FIG. 2 is a cross-sectional view of the ultrasound transducer 10. In the illustrated embodiment, the ultrasound transducer 10 includes an acoustic element 12, a lens 14, and a backing layer 16. The ultrasound transducer 10 may also include other layers, such as, but not limited to, an integrated circuit (not shown), a flex circuit (not shown), and/or a heat sink (not shown). The backing layer 16 may be a relatively high acoustic attenuation material to dampen backside acoustic energy.

In the illustrated embodiment, the ultrasound transducer 10 is a transducer for a catheter and/or guide wire based IVUS imaging system. But, the ultrasound transducer 10 may be used with any other type of ultrasound system, for example traditional ultrasound systems that include a probe for performing ultrasound imaging from a position outside (i.e., exterior to) a target (i.e., a body and/or other volume).

The acoustic element 12, the lens 14, and the backing layer 16 are arranged in a stack in the illustrated embodiment, as can be seen in FIGS. 1 and 2. Within the stack, the acoustic element 12 is disposed between the lens 14 and the backing layer 16. Other relative arrangements of the acoustic element 12, the lens 14, and the backing layer 16 may be provided in addition or alternative to the illustrated stack.

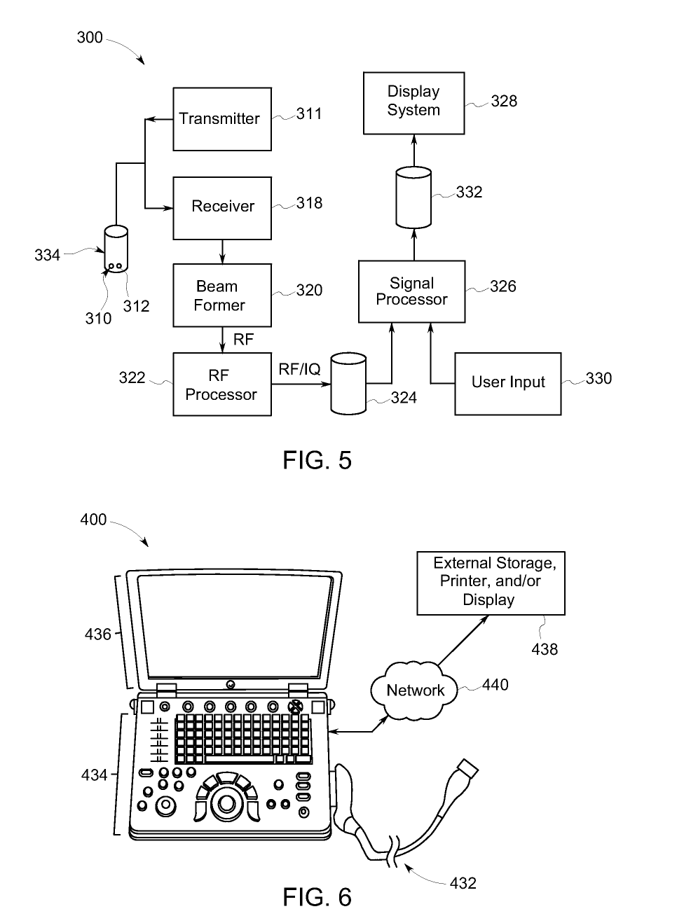

The acoustic element 12 is configured to be electrically connected to one or more other components of an ultrasound system (e.g., the ultrasound system 300 shown in FIG. 5). For example, the acoustic element 12 may be electrically connected to an integrated circuit (not shown), an RF processor (e.g., the RF processor 322 shown in FIG. 5), a memory (e.g., the memory 324 and/or the memory 332 shown in FIG. 5), a signal processor (e.g., the signal processor 326 shown in FIG. 5), a user input (e.g., the user input 330 shown in FIG. 5), and/or a display system (e.g.,. the display system 328 shown in FIG. 5).

In embodiments wherein the ultrasound transducer 10 includes an integrated circuit and/or a flex circuit, the integrated circuit and/or flex circuit may provide the electrical connection between the acoustic element 12 and the other component(s) of the ultrasound system. For example, the integrated circuit and/or the flex circuit may be disposed within the stack between the acoustic element 12 and the backing layer 16 such that the integrated and/or the flex circuit is electrically connected to the acoustic element 12. In embodiments wherein the ultrasound transducer 10 includes a heat sink, the heat sink is connected (whether directly or indirectly) to the backing layer 16 for dissipating heat from the ultrasound transducer 10. For example, the heat sink may be directly connected to (i.e., engaged in physical contact with) a back side 18 of the backing layer 16 or may be indirectly connected to the back side 18 of the backing layer 16 through one or more additional structures and/or components, such as, but limited to, a thermal interface material (TIM), an integrated circuit, a flex circuit, and/or the like. Optionally, the ultrasound transducer 10 includes a backside matching layer (not shown) disposed between the integrated and/or flex circuit and the backing layer 16.

Although only a single acoustic element 12 is shown herein, the acoustic element 12 is optionally arranged in an array with a plurality of other acoustic elements 12. The array of acoustic elements 12 are optionally electrically connected to a single integrated and/or flex circuit for providing the electrical connection between the acoustic elements 12 and the other component(s) of the ultrasound system. Moreover, the array of acoustic elements 12 are optionally connected in thermal communication with a single heat sink for dissipating heat from the acoustic elements 12. The array of acoustic elements 12 may be arranged in a one dimensional (1D) array, a 1.5D array, a 1.75D array, a two-dimensional (2d) array, and/or the like. A variety of geometries may also be used, such as, but not limited to, linear, curved, cylindrical, and/or the like.

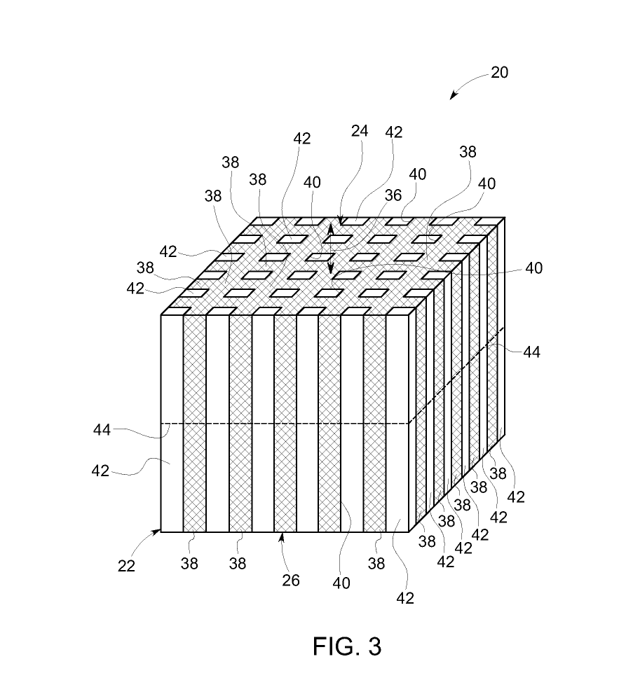

Each acoustic element 12 includes an acoustic layer 20 that is formed from a micromachined piezoelectric composite body 22. The micromachined piezoelectric composite body 22 will be described in more detail below with reference to FIG. 3. The micromachined piezoelectric composite body 22 of the acoustic layer 20 includes a front side 24 and a back side 26 that is opposite the front side 24. For purposes of this disclosure, the front side 24 is defined to include the side of the acoustic layer 20 from which ultrasound waves are emitted towards the lens 14. The back side 26 is defined to include the side of the acoustic layer 20 that is opposite of the front side 24 and that faces away from the lens 14.

The lens 14 is connected to the front side 24 of the acoustic layer 20. The acoustic element 12 includes one or more other layers in addition to the acoustic layer 20. For example, the acoustic element 12 includes one or more dematching layers 28. Optionally, the acoustic element 12 additionally includes one or more frontside matching layers 30 and/or one or more conductive film layers (not shown). Each acoustic element 12 may include any number of layers overall. In the illustrated embodiment, the acoustic element 12 includes three frontside matching layers 30a, 30b, and 30c. But, each acoustic element 12 may include any number of frontside matching layers 30. For example, some embodiments may include only one front side matching layer 30, while other embodiments may include only two or four or more frontside matching layers 30.

In the illustrated embodiment, the lens 14 is indirectly connected to the front side 24 of the micromachined piezoelectric composite body 22 of the acoustic layer 20 through the frontside matching layers 30, which are disposed between the acoustic layer 20 and the lens 14. Alternatively, the lens 14 is directly connected to (i.e., engaged in physical contact with) the front side 24 of the acoustic layer 20. In some embodiments, the frontside matching layers 30, the acoustic layer 20, and/or the lens 14 are bonded together using epoxy and/or other adhesive material (e.g., cured under pressure), such as, but not limited to, a material supplied by tooling including a press machine and/or the like.

The lens 14 may have any acoustic impedance. For example, in some embodiments, the lens 14 has an acoustic impedance of approximately 1.5 MRayls. Other examples of the acoustic impedance of the lens 14 include, but are not limited to, embodiments wherein the lens 18 has an acoustic impedance anywhere in the range of approximately 1.2 MRayls to approximately 1.6 MRayls.

The frontside matching layers 30 are disposed between the acoustic layer 20 and the lens 14 to increase the energy of the waves transmitted from the ultrasound transducer 10. The acoustic impedance of each frontside matching layer 30 may be selected to reduce a possible mismatch of acoustic impedances between the acoustic layer 20 and the lens 14. The frontside matching layers 30 may result in less reflection and/or refraction of ultrasound waves between the acoustic layer 20 and the lens 14.

Each frontside matching layer 30 may have any value of acoustic impedance, such as, but not limited to, between approximately 1 MRayl and approximately 20 MRayls, between approximately 5 MRayls and approximately 15 MRayls, less than approximately 16 MRayls, between approximately 2 MRayls and approximately 8 MRayls, less than approximately 9 MRayls, among others. In the illustrated embodiment, the frontside matching layer 30a has an acoustic impedance of approximately 10-20 MRayls, the frontside matching layer 30b has an acoustic impedance of approximately 5-15 MRayls, and the frontside matching layer 30c has an acoustic impedance of approximately 2-8 MRayls. In some embodiments, each frontside matching layer 30 has an acoustic impedance that is less than the acoustic impedance of the acoustic layer 20.

In embodiments wherein the acoustic element 12 includes a plurality of the frontside matching layers 30, the frontside matching layers optionally provide a progressive reduction in acoustic impedance from the acoustic layer 20. For example, in some embodiments, the frontside matching layer 30 closest to the acoustic layer 20 (e.g., the frontside matching layer 30a) is approximately 15 MRayls, the next frontside matching layer 30 (e.g., the frontside matching layer 30b) is approximately 8 MRayls, and the frontside matching layer 30 farthest from the acoustic layer 20 (e.g., the frontside matching layer 30c) is approximately 3 MRayls. Optionally, each of the frontside matching layers 30 has a relatively high thermal conductivity, such as, but not limited to, greater than approximately 30 W/mK.

Each frontside matching layer 30 may have any thickness and the frontside matching layers 30 may have any combined thickness. One example of a thickness of a frontside matching layer 30 includes a thickness of approximately ¼ or less of the wavelength at the resonant frequency of the ultrasound transducer 10. But, a frontside matching layer 30 may be more than approximately ¼ of the wavelength at the resonant frequency of the ultrasound transducer 10. For example, one or more of the frontside matching layers 30 may be approximately ½ of the wavelength at the resonant frequency. In some embodiments, each of the frontside matching layers 30 is approximately ¼ of the desired wavelength or less in order to minimize destructive interference caused by waves reflected from the boundaries between each of the frontside matching layers 30.

Each of the frontside matching layers 30 may be any type of matching layer that is formed from any material(s) that enables the frontside matching layer 30 to function as described and/or illustrated herein, such as, but not limited to, an epoxy, a filled epoxy that is filled with one or more different fillers, metal-impregnated graphite, glass ceramic, composite ceramic, metal (such as, but not limited to, copper, copper alloy, copper with graphite pattern embedded therein, magnesium, magnesium alloy, aluminum, aluminum alloy, and/or the like), and/or the like. Any fillers that are used (e.g., with a filled epoxy) are optionally used to adjust the acoustic impedance of the frontside matching layer 30.

Each frontside matching layer 30 may be electrically conductive or electrically non-conductive. When a frontside matching layer 30 is electrically non-conductive, the frontside matching layer 30 optionally includes a conductive film layer (not shown) thereon. One or more frontside matching layers 30 (and/or a conductive film layer thereon) may provide an electrical ground connection for the acoustic element 12.

The dematching layer 28 of the acoustic element 12 is disposed between the backing layer 16 and the back side 26 of the acoustic layer 20. In the illustrated embodiment, the dematching layer 16 is directly connected to (i.e., engaged in physical contact with) the back side 26 of the acoustic layer 20. Alternatively, the dematching layer 28 is indirectly connected to the back side 26 of the acoustic layer 20 through one or more additional structures and/or components disposed between the dematching layer 28 and the back side 26 of the acoustic layer 20. In some embodiments, the dematching layer 28 is bonded with the acoustic layer 20 using epoxy and/or other adhesive material (e.g., cured under pressure), such as, but not limited to, a material supplied by tooling including a press machine and/or the like.

The dematching layer 28 has a higher acoustic impedance than the acoustic layer 20 to increase the power of the ultrasound waves transmitted to the lens 18. In other words, the dematching layer 28 has a higher acoustic impedance than the micromachined piezoelectric composite body 22 of the acoustic layer 20. The dematching layer 28 has a relatively high acoustic impedance (e.g., at least approximately 39 MRayls) and functions to clamp the acoustic layer 20 so that a majority of the acoustic energy is transmitted out through the front side 24 of the acoustic layer 20. However, a relatively small amount of backside acoustic energy can still be reflected back to the front side 24, which can cause artifacts in ultrasound images generated from ultrasound signals acquired by the ultrasound transducer 10. Therefore, the backing layer 16 may be provided with a relatively high acoustic attenuation material to damp down such backside acoustic energy (i.e., to reduce acoustic reverberation inside the ultrasound transducer 10). Consequently, a majority of the acoustic energy is reflected out the front side 24 of the acoustic layer 20. In addition to the backing layer 16, the relatively high acoustic impedance of the dematching layer 28 may also facilitate reducing acoustic reverberation inside the ultrasound transducer 10. Moreover, the relatively high acoustic impedance of the dematching layer 28 may prevent at least some acoustic waves from propagating in the backward direction (shown in FIGS. 1 and 2 by the arrow 32), which may enable the ultrasound transducer 10 to transmit more energy in the forward direction (shown in FIGS. 1 and 2 by the arrow 34).

The backing layer 18 may be any type of backing layer that is formed from any material(s), such as, but not limited to, an epoxy with a filler such as, but not limited to, titanium dioxide and/or the like. The backing layer 16 may have any thickness, such as, but not limited to, approximately 2 mm thick, from 1 mm to approximately 20 mm thick, among others.

In the illustrated embodiment, the acoustic element 12 includes a single dematching layer 28. But, the acoustic element 12 may include any number of dematching layers 28, for example two or more dematching layers 28. Each dematching layer 28 may have any value of acoustic impedance, such as, but not limited to, at least approximately 40 MRayls, between approximately 39 MRayls and approximately 121 MRayls, between approximately 59 MRayls and approximately 101 MRayls, greater than approximately 70 MRayls, and/or the like. The dematching layer 28 may have relatively good thermal conductivity that can carry over, or transfer, heat generated by the acoustic layer 20 to the backing layer 16.

The dematching layer 28 may be any type of dematching layer that is formed from any material(s), such as, but not limited to, metal, a carbide alloy and/or compound material (e.g., zirconium, tungsten, tungsten carbide, silicon, titanium, tantalum carbide, and/or the like) and/or the like. Each dematching layer 28 may have any thickness and, in embodiments wherein a plurality of dematching layers 28 are provided, the dematching layers 28 may have any combined thickness. The thickness of one or more dematching layers 28 may depend on the frequency of the ultrasound transducer 10. Examples of the thickness of a dematching layer 28 include, but are not limited to, between approximately 49 um and approximately 351 um. The dematching layer 28 may be laminated to the acoustic layer 20 using any suitable method, structure, process, means, and/or the like, such as, but not limited to, using epoxy having an exemplary thickness of less than approximately 5 um.

In some embodiments, the dematching layer 28 is coated with an electrically conductive coating (not shown) of metal and/or another electrical conductor. The electrically conductive coating may facilitate electrical connection between the dematching layer 34 and one or more other components of the ultrasound transducer 10 and/or the ultrasound system. The dematching layer 28 may be coated with the electrically conductive coating using any suitable method, structure, process, means, and/or the like. One example of forming the electrically conductive coating on the dematching layer 28 is to first sputter with Ni or Cr material as a seed layer (e.g., less than approximately 0.1 um) and then add a layer of gold (e.g., less than approximately 1 um). The layer of gold may then be electroplated or electrolysis with Ni (e.g., less than approximately Sum) and gold (e.g., less than approximately 0.2 um) on the outside to prevent oxidation. In some embodiments, and in addition or alternatively to the electrically conductive coating on the dematching layer 28, the acoustic element 12 may be provided with electrical contacts (not shown; and having any other structure than the electrically conductive coating) for electrical connection with other components. Such electrical contacts of the acoustic element 12 may be, but are not limited to, solder pads, solder bumps, stud bumps, plated bumps, and/or the like.

As briefly described above, the acoustic layer 20 includes the micromachined piezoelectric composite body 22. FIG. 3 is a perspective view of an embodiment of the micromachined piezoelectric composite body 22 of the acoustic layer 20. The micromachined piezoelectric composite body 22 is configured to generate and transmit acoustic energy into a target (i.e., a body and/or other volume) and receive backscattered acoustic signals from the target to create and display an image. In other words, the micromachined piezoelectric composite body 22 of the acoustic layer 20 is configured to convert electrical signals into ultrasound waves to be transmitted from the front side 24 of the acoustic layer 20 toward the target, and the micromachined piezoelectric composite body 22 is configured to convert received ultrasound waves into electrical signals. Arrows 36 depict ultrasound waves transmitted from and received at the ultrasound transducer 10. The acoustic layer 20 may include electrodes (not shown) for electrical connection.

The micromachined piezoelectric composite body 22 of the acoustic layer 20 includes piezoelectric posts 38 that are separated from each other by voids 40. The voids 40 are filled with a filler material that is a different substance (i.e., composition) than the piezoelectric posts (e.g., the filter material does not include a piezoelectric substance), such as, but not limited to, a polymer, an epoxy and/or the like. Accordingly, the micromachined piezoelectric composite body 22 includes the piezoelectric posts 38 and filler members 42 that extend between the piezoelectric posts 38. The body 22 is referred to as a “composite” body because the body includes both the piezoelectric substance of the piezoelectric posts 38 and the different substance of the filler members 42.

The piezoelectric posts 38 may be formed from any piezoelectric substance, such as, but not limited to, a piezoelectric crystal material (i.e., a piezoelectric substance having a crystalline structure), an amorphous piezoelectric material (i.e., a piezoelectric substance having an amorphous structure), a piezoelectric ceramic, and/or the like. In embodiments wherein the piezoelectric substance of the piezoelectric posts 38 includes a piezoelectric crystal material, the piezoelectric crystal material may have a single crystal structure (i.e., a monocrystalline structure) or may have a crystalline structure that is not continuous. One specific example of a piezoelectric crystal material that the piezoelectric posts 38 may be formed from is lead magnesium niobate-lead titanate (PMN-PT). Another example of a piezoelectric substance that the piezoelectric posts 38 may be formed from is lead zinc niobate-lead titanate (PZN-PT). Other examples of piezoelectric substances that the piezoelectric posts 38 may be formed from include, but are not limited to, lead zirconate titanate (PZT), PIN-PMN-PT, and/or the like). The piezoelectric substance used to form the piezoelectric posts 38 may have any dielectric constant, such as, but not limited to, a dielectric constant anywhere in the range from approximately 4000 to approximately 7700 or greater than approximately 7700. The piezoelectric substance used to form the piezoelectric posts 38 may have any dielectric loss, such as, but not limited to, a dielectric loss of less than 0.01.

The filler members 42 may be formed from any substance that is a different substance (i.e., has a different composition) than the piezoelectric posts (e.g., the filter material does not include a piezoelectric substance), such as, but not limited to, a polymer, an epoxy, and/or the like. Examples of suitable epoxies for forming the filler members 42 include, but are not limited to, Epo-Tek-301 (commercially available from Epoxy Technology, Inc. of Billerica, Mass.), Epo-Tek-301-2 (commercially available from Epoxy Technology, Inc. of Billerica, Mass.), and/or the like.

The micromachined piezoelectric composite body 22 may include any number of the piezoelectric posts 38 and any number of the filler members 42. Each piezoelectric post 38 may have any size and any shape. In the illustrated embodiment, the piezoelectric posts 38 have the shape of parallelepipeds (i.e., a rectangular, and more specifically a square, cross-sectional shape taken along the plane 44 of FIG. 3). But, each piezoelectric post 38 additionally or alternatively may include any other shape, such as, but not limited to, a triangular cross-sectional shape taken along the plane 44, a different rectangular shape taken along the plane 44, a circular cross-sectional shape taken along the plane 44, an oval cross-sectional shape taken along the plane 44, a curved cross-sectional shape taken along the plane 44, a two-sided cross-sectional shape taken along the plane 44, an octagonal cross-sectional shape taken along the plane 44, a cross-sectional shape taken along the plane 44 having at least five sides, a star-shaped cross-sectional shape taken along the plane 44, and/or the like. Although show as square, the rectangular cross-sectional shape of the piezoelectric posts 38 may have any aspect ratio between the length and width of the rectangle. In some embodiments, the shape of one or more of the piezoelectric posts 38 is not consistent along the height of the piezoelectric post 38 defined between the front side 24 and the back side 26.

In the illustrated embodiment, the voids 40, and therefore the filler members 42, have a square cross-sectional shape taken along the plane 44. But, additionally or alternatively, each void 40 and filler member 42 may include any other shape, such as, but not limited to, a triangular cross-sectional shape taken along the plane 44, a different rectangular shape taken along the plane 44, a circular cross-sectional shape taken along the plane 44, an oval cross-sectional shape taken along the plane 44, a curved cross-sectional shape taken along the plane 44, a two-sided cross-sectional shape taken along the plane 44, an octagonal cross-sectional shape taken along the plane 44, a cross-sectional shape taken along the plane 44 having at least five sides, a star-shaped cross-sectional shape taken along the plane 44, and/or the like. In embodiments wherein the voids 40 and corresponding filler members 42 have rectangular cross-sectional shapes, each void 40 and the corresponding filler member 42 may have any aspect ratio between the length and width of the rectangle. In some embodiments, the shape of one or more of the voids 40 and the corresponding filler member 42 is not consistent along the height of the void 40 and filler member 42 defined between the front side 24 and the back side 26.

The array of the piezoelectric posts 38 and the filler members 42 are not limited to the grid-like pattern shown herein. Rather, the grid-like pattern of the piezoelectric posts 38 and the filler members 42 shown herein is meant as exemplary only. The array of the piezoelectric posts 38 and the filler members 42 may be arranged in any other pattern relatively to each other. For example, the voids 40 may have any size such that the piezoelectric posts 38 are spaced apart by any amount, which may or may not be consistent throughout the pattern of the piezoelectric posts 38 and the filler members 42. The pattern of the piezoelectric posts 38 and the filler members 38 may be selected to provide the micromachined piezoelectric composite body 22 with any type of imaging transducer configuration, such as, but not limited to, a 2-2 configuration, a 1-3 configuration, and/or the like. The pattern of the array of piezoelectric posts 38 and the filler members 38 enables any pattern of imaging elements (i.e., ultrasound transducers) to be formed, such as, but not limited to, one dimensional arrays of imaging elements, two dimensional arrays of imaging elements, and/or the like.

Although shown as having a square shape (e.g., the shape of the perimeter of the body 22 taken along the plane 44), the array of the piezoelectric posts 38 and the filler members 42 additionally or alternatively may include any other shape, such as, but not limited to, a triangular shape, a different rectangular shape, a circular shape, an oval shape, a curved shape, a two-sided shape, an octagonal shape, a shape having at least five sides, a star shape, and/or the like. Circular and/or other curved shaped arrays of the piezoelectric posts 38 and the filler members 42 may be particularly suited for intravascular use. For example, a circular and/or other curved shaped array of the piezoelectric posts 38 and the filler members 42 may be forward facing in an imaging catheter and/or on a guidewire.

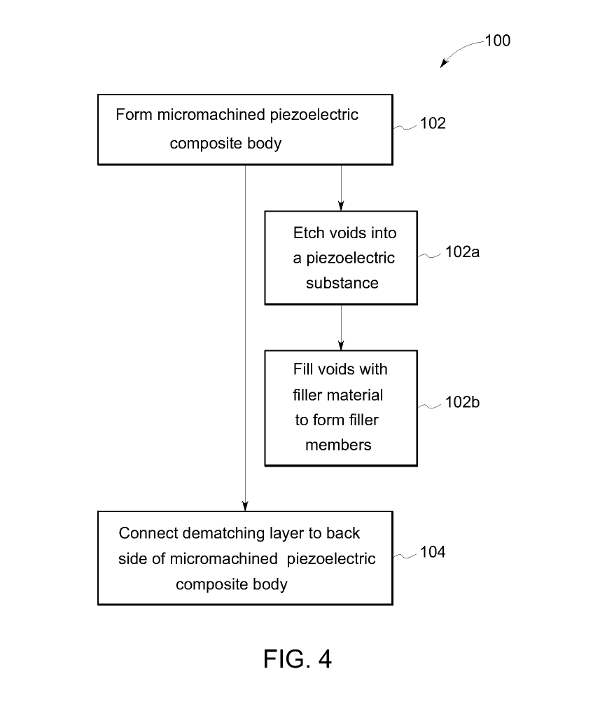

The micromachined piezoelectric composite body 22 of the acoustic layer 20 may be formed using any process, method, structure, and/or the like. By “micromachined”, it is meant that the body 22 is formed using any etching process, such as, but not limited to, reactive ion etching (RIE), deep reactive ion etching (DRIE), laser etching, plasma etching, wet etching, photolithography, and/or the like. Exemplary (i.e., non-limiting) examples of the formation of the micromachined piezoelectric composite body 22 are described below with reference to FIG. 4.

Referring again to FIGS. 1 and 2, the imaging resolution of the ultrasound transducer 10 is inversely proportional to the frequency bandwidth of the ultrasound transducer 10. A transducer with a relatively broad bandwidth is able to generate relatively short ultrasonic pulses, which may facilitate distinguishing close targets in the axial direction. The bandwidth of the ultrasound transducer 10 is affected by various parameters, which may include the electromechanical coupling coefficient (kt) of the acoustic layer 20, the piezoelectric coefficient (dt) of the acoustic layer 20, the acoustic impedance of the acoustic layer 20, the acoustic matching schemes of the ultrasound transducer 10, and/or the like.

The micromachined piezoelectric composite body 22 of the acoustic layer 20 has a relatively high electromechanical coupling coefficient kt (e.g., at least approximately 0.7) and a relatively low acoustic impedance (e.g., less than approximately 36 MRayls). For example, the micromachined piezoelectric composite body 22 of the acoustic layer 20 may have an electromechanical coupling coefficient kt of at least approximately 0.7. In other embodiments, the micromachined piezoelectric composite body 22 of the acoustic layer 20 has an electromechanical coupling coefficient kt of at least approximately 0.8 or at least approximately 0.9. Moreover, the micromachined piezoelectric composite body 22 of the acoustic layer 20 may have a piezoelectric coefficient dt of at least approximately 1500 pC/N. In other embodiments, the micromachined piezoelectric composite body 22 of the acoustic layer 20 has a piezoelectric coefficient dt of at least approximately 1750 pC/N. Moreover, and for example, the micromachined piezoelectric composite body 22 of the acoustic layer 20 may have any value of acoustic impedance, such as, but not limited to, less than approximately 36 MRayls. In some embodiments, the micromachined piezoelectric composite body 22 has an acoustic impedance of between approximately 3 MRayls and approximately 35 MRayls. In other embodiments, the micromachined piezoelectric composite body 22 has an acoustic impedance of approximately 30 MRayls or anywhere in the range of approximately 20 MRayls to approximately 40 MRayls. As described above, the value of the acoustic impedance of the micromachined piezoelectric composite body 22 is less than the value of the acoustic impedance of the dematching layer 28.

The relatively high electromagnetic coupling coefficient kt of the micromachined piezoelectric composite body 22 may facilitate relatively efficiently convert mechanical energy to electrical energy, and vice versa, which may facilitate both transmitting and receiving ultrasonic waves. The relatively low acoustic impedance of the micromachined piezoelectric composite body 22 (and/or the lesser value as compared to the acoustic impedance of the dematching layer 28) may facilitate relatively efficiently propagating acoustic energy between the loading medium (e.g., water) and the ultrasound transducer 10, which may facilitate increasing the sensitivity and/or bandwidth of the ultrasound transducer 10 by reducing the acoustic reverberation inside the ultrasound transducer 10.

The ultrasound transducer 10 may have an increased bandwidth as compared to at least some known ultrasound transducers, for example as compared to at least some known IVUS transducers. For example, the ultrasound transducer 10 may have a bandwidth of at least approximately 70%. In some embodiments, the ultrasound transducer 10 has a bandwidth of at least approximately 80% or at least approximately 100%. The ultrasound transducer 10 may operate at a relatively high frequency (e.g., a frequency of at least 20 MHz), which may be a higher frequency as compared to at least some known ultrasound transducers, for example as compared to at least some known IVUS transducers. For example, the ultrasound transducer 10 may operate at a frequency of at least 20 MHz or anywhere in the range from approximately 30 MHz to approximately 80 MHz.

The relatively high frequency and/or the increased bandwidth of the ultrasound transducer 10 increases the imaging resolution and/or the image depth of the ultrasound transducer 10. For example, the increased bandwidth of the ultrasound transducer 10 may improve the axial resolution of the ultrasound transducer 10, which may increase the imaging depth. Such an improved imaging resolution may be beneficial for identifying microstructures of atherosclerotic plaques. Moreover, the increased bandwidth of the ultrasound transducer 10 may facilitate applying various signal and/or imaging processing methods to facilitate identifying plaque. Further, the ultrasound transducer 10 may have an improved sensitivity because of the relatively low acoustic impedance of the acoustic layer 20 (specifically the body 22) and the relatively high acoustic impedance of the dematching layer 28. Such an improved sensitivity may be beneficial for enabling ultrasound waves to penetrate through blood and into a vessel wall, which may increase the dynamic range and/or penetration depth of the ultrasound transducer 10.

FIG. 4 is a flowchart illustrating a method 100 for manufacturing an ultrasound transducer in accordance with various embodiments. Exemplary uses of the method 100 include manufacturing the ultrasound transducer 10 shown in FIGS. 1 and 2. The method 100 includes, at 102, forming a micromachined piezoelectric composite body (e.g., the micromachined piezoelectric composite body 22 shown in FIGS. 1-3). Forming at 102 the micromachined piezoelectric composite body includes etching, at 102a, voids (e.g., the voids 40 shown in FIG. 3) into a piezoelectric substance to provide the piezoelectric substance with piezoelectric posts (e.g., the piezoelectric posts 38 shown in FIG. 3) that are separated from each other by the voids.

The piezoelectric substance that is etched at 102a may be provided as a block or plate, or any other shape. As described above with respect to the piezoelectric posts 38, the piezoelectric substance may be any piezoelectric substance, such as, but not limited to, a piezoelectric crystal material, an amorphous piezoelectric material, a piezoelectric ceramic, PMN-PT, PZN-PT, PZT, PIN-PMN-PT, and/or the like. The etching step 102a may be performed using any etching process, such as, but not limited to, RIE, DRIE, laser etching, plasma etching, wet etching, photolithography, and/or the like. Optionally, the formation at 102 of the micromachined piezoelectric composite body includes applying a mask of photoresist to the piezoelectric substance to define the desired shape and/or pattern of the voids.

At 102b, forming at 102 the micromachined piezoelectric body includes filling the voids with a filler material to form filler members (e.g., the filler members 42 shown in FIG. 3) that extend between the piezoelectric posts. As described above with respect to the filler members 42, the filler material is any substance that is a different substance than the piezoelectric substance that forms the piezoelectric posts, such as, but not limited to, a polymer, an epoxy and/or the like.

Optionally, forming at 102 the micromachined piezoelectric body includes lapping the body such that the body includes a front side (e.g., the front side 24 shown in FIGS. 1-3) and an opposite back side (e.g., the back side 26 shown in FIGS. 1-3). Moreover, forming at 102 the micromachined piezoelectric body optionally includes forming an electrode pattern (not shown) on the front and/or back side of the micromachined piezoelectric body.

At 104, the method 100 includes connecting a dematching layer (e.g., the dematching layer 28 shown in FIGS. 1 and 2) to the back side of the micromachined piezoelectric composite body. As described above with respect to the dematching layer 28 and the micromachined piezoelectric composite body 22, the dematching layer has a higher acoustic impedance than an acoustic impedance of the micromachined piezoelectric composite body formed at 102.

The method 100 may include connecting one or more other layers and/or components to the micromachined piezoelectric composite body formed at 102 and/or to the dematching layer connected at 104. For example, the method 100 may include connecting, whether directly or indirectly, a lens (e.g., the lens 14 shown in FIGS. 1 and 2), one or more front side matching layers (e.g., the matching layers 30a, 30b, and 30c), a backing layer (e.g., the backing layer 18 shown in FIGS. 1 and 2), an integrated and/or flex circuit, a heat sink, and/or the like to the micromachined piezoelectric composite body and/or to the dematching layer.

The embodiments of the ultrasound transducers described and/or illustrated herein may be used with any type of ultrasound imaging system and may be used for any type of medical and/or other application, such as, but not limited to, with a catheter and/or guide wire based IVUS imaging system, with a traditional ultrasound system that includes a probe for performing ultrasound imaging from a position outside (i.e., exterior to) a target (i.e., a body and/or other volume), for the diagnosing atherosclerosis, for imaging the anterior region of the eye (e.g., for monitoring surgical procedures such as, but not limited to, cataract treatment, lens replacement, laser in situ keratomileusis [LASIK], and/or the like), for tumor detection, for skin imaging (e.g., for caring for burn victims, for melanoma detection, and/or the like), for intra-articular imaging (e.g., for detection of pre-arthritis conditions and/or the like), for in-vivo mouse embryo imaging (e.g., for medical research and/or the like), for Doppler ultrasound (e.g., for determining blood flow in vessels and/or the like), for intracardiac and/or intravascular imaging, for ultrasound guidance (e.g., for the biopsy of tissue and/or the like), and/or the like.

FIG. 5 is a block diagram of an ultrasound system 300 in which various embodiments may be implemented. The ultrasound system 300 may be used, for example, to acquire ultrasound data and generate ultrasound images. In the illustrated embodiment, the ultrasound system 300 is a catheter and/or guide wire based IVUS imaging system. The ultrasound system 300 includes a transmitter 311 that drives an array of acoustic elements 312 within or formed as part of an ultrasound transducer 310 to emit pulsed ultrasonic signals into a body or other volume. The ultrasonic signals are back-scattered from density interfaces and/or structures in the body or other volume (e.g., blood cells, blood vessels, fatty tissue, and/or muscular tissue in a body) to produce echoes that return to the acoustic elements 312. The echoes are received by a receiver 318. The received echoes are passed through beamforming electronics 320, which performs beamforming and outputs an RF signal. The RF signal then passes through an RF processor 322. The RF processor 322 may include a complex demodulator (not shown) that demodulates the RF signal to form IQ data pairs representative of the echo signals. The RF or IQ signal data may then be routed directly to a memory 324 for storage (e.g., temporary storage).

The ultrasound system 300 also includes a signal processor 326 to process the acquired ultrasound information (e.g., RF signal data or IQ data pairs) and prepare frames of ultrasound information for display on a display system 328. The signal processor 326 is adapted to perform one or more processing operations according to a plurality of selectable ultrasound modalities on the acquired ultrasound information. Acquired ultrasound information may be processed and/or displayed in real-time during a scanning session as the echo signals are received. Additionally or alternatively, the ultrasound information may be stored temporarily in the memory 324 during a scanning session and then processed and/or displayed in less than real-time in a live or off-line operation.

The signal processor 326 is connected to a user input device 330 that may control operation of the ultrasound system 300. The user input device 330 may be any suitable device and/or user interface for receiving user inputs to control, for example, the type of scan or type of transducer to be used in a scan. The display system 328 includes one or more monitors that present patient information, including diagnostic ultrasound images to the user for diagnosis and/or analysis. The ultrasound system 300 may include a memory 332 for storing processed frames of acquired ultrasound information that are not scheduled to be displayed immediately. One or both of the memory 324 and the memory 332 may store three-dimensional (3D) data sets of the ultrasound data, where such 3D datasets are accessed to present 2D and/or 3D images. Multiple consecutive 3D datasets may also be acquired and stored over time, such as to provide real-time 3D or 4D display. The images may be modified and/or the display settings of the display system 328 may be manually adjusted using the user input device 30.

In addition to the acoustic elements 312, various other components of the ultrasound system 300 may be considered to be a component of the ultrasound transducer 310. For example, the transmitter 311, the receiver 318, and/or the beamforming electronics 320 may each be a component of the ultrasound transducer 310. In some embodiments, two or more components of the ultrasound system 300 are integrated into an integrated circuit, which may be a component of the ultrasound transducer 310. For example, the transmitter 312, the receiver 318, and/or the beamforming electronics 320 may be integrated into an integrated circuit.

The ultrasound system 300 may include an ultrasound probe 334 that holds one or more various components of the ultrasound transducer 310. For example, as shown in FIG. 5, the ultrasound probe 334 holds the array of acoustic elements 312. In the illustrated embodiment, the ultrasound probe 334 is configured to be positioned within the lumen (not shown) of a guide wire (not shown) and/or catheter (not shown). In addition to the acoustic elements 312, and for example, the ultrasound probe 334 may hold the transmitter 311, the receiver 318, the beamforming electronics 320, and/or one or more integrated circuits that include any of the components 311, 318, and/or 320.

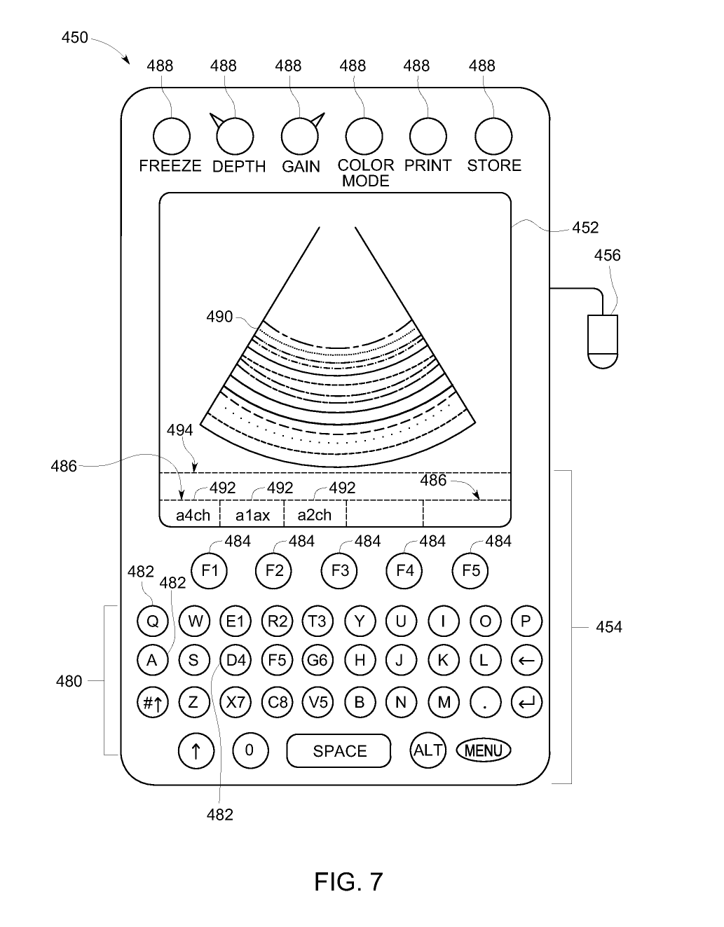

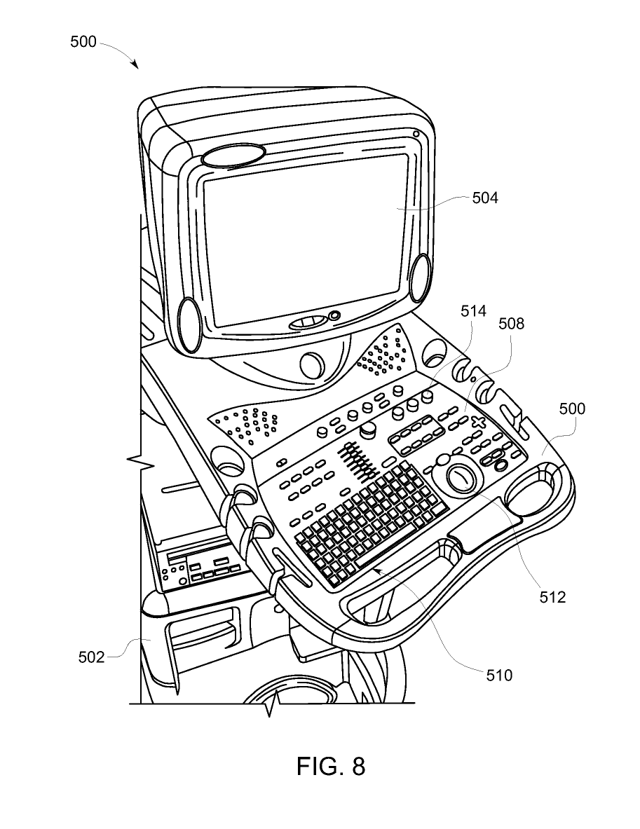

The ultrasound system 300 may be embodied in a small-sized system, such as, but not limited to, a laptop computer or pocket sized system as well as in a larger console-type system. FIGS. 6 and 7 illustrate small-sized systems, while FIG. 8 illustrates a larger system.

FIG. 6 illustrates a 3D-capable miniaturized ultrasound system 400 having an ultrasound transducer 432 that may be configured to acquire 3D ultrasonic data or multi-plane ultrasonic data. For example, the ultrasound transducer 432 may have a 2D array of acoustic elements. A user interface 434 (that may also include an integrated display 436) is provided to receive commands from an operator. As used herein, “miniaturized” means that the ultrasound system 430 is a handheld or hand-carried device or is configured to be carried in a person's hand, pocket, briefcase-sized case, or backpack. For example, the ultrasound system 430 may be a hand-carried device having a size of a typical laptop computer. The ultrasound system 430 is easily portable by the operator. The integrated display 436 (e.g., an internal display) is configured to display, for example, one or more medical images.

The ultrasonic data may be sent to an external device 438 via a wired or wireless network 440 (or direct connection, for example, via a serial or parallel cable or USB port). In some embodiments, the external device 438 may be a computer or a workstation having a display, or the DVR of the various embodiments. Alternatively, the external device 438 may be a separate external display or a printer capable of receiving image data from the hand carried ultrasound system 430 and of displaying or printing images that may have greater resolution than the integrated display 436.

FIG. 7 illustrates a hand carried or pocket-sized ultrasound imaging system 450 wherein the display 452 and user interface 454 form a single unit. By way of example, the pocket-sized ultrasound imaging system 450 may be a pocket-sized or hand-sized ultrasound system approximately 2 inches wide, approximately 4 inches in length, and approximately 0.5 inches in depth and weighs less than 3 ounces. The pocket-sized ultrasound imaging system 450 generally includes the display 452, user interface 454, which may or may not include a keyboard-type interface and an input/output (I/O) port for connection to a scanning device, for example, and an ultrasound transducer 456. The display 452 may be, for example, a 320×320 pixel color LCD display (on which a medical image 484 may be displayed). A typewriter-like keyboard 480 of buttons 482 may optionally be included in the user interface 454.

Multi-function controls 484 may each be assigned functions in accordance with the mode of system operation (e.g., displaying different views). Therefore, each of the multi-function controls 484 may be configured to provide a plurality of different actions. Label display areas 486 associated with the multi-function controls 484 may be included as necessary on the display 452. The system 450 may also have additional keys and/or controls 488 for special purpose functions, which may include, but are not limited to “freeze,” “depth control,” “gain control,” “color-mode,” “print,” and “store.”

One or more of the label display areas 486 may include labels 492 to indicate the view being displayed or allow a user to select a different view of the imaged object to display. The selection of different views also may be provided through the associated multi-function control 484. The display 452 may also have a textual display area 494 for displaying information relating to the displayed image view (e.g., a label associated with the displayed image).

It should be noted that the various embodiments may be implemented in connection with miniaturized or small-sized ultrasound systems having different dimensions, weights, and power consumption. For example, the pocket-sized ultrasound imaging system 450 and the miniaturized ultrasound system 400 may provide the same scanning and processing functionality as the system 300 (shown in FIG. 5)

FIG. 8 illustrates an ultrasound imaging system 500 provided on a movable base 502. The portable ultrasound imaging system 500 may also be referred to as a cart-based system. A display 504 and user interface 506 are provided and it should be understood that the display 504 may be separate or separable from the user interface 506. The user interface 506 may optionally be a touchscreen, allowing the operator to select options by touching displayed graphics, icons, and/or the like.

The user interface 506 also includes control buttons 508 that may be used to control the portable ultrasound imaging system 500 as desired or needed, and/or as typically provided. The user interface 506 provides multiple interface options that the user may physically manipulate to interact with ultrasound data and other data that may be displayed, as well as to input information and set and change scanning parameters and viewing angles, etc. For example, a keyboard 510, trackball 512 and/or multi-function controls 514 may be provided.

It should be noted that although the various embodiments may be described in connection with an ultrasound system, the methods and systems are not limited to ultrasound imaging or a particular configuration thereof. The various embodiments of ultrasound imaging may be implemented in combination with different types of imaging systems, for example, multi-modality imaging systems having an ultrasound imaging system and one of an x-ray imaging system, magnetic resonance imaging (MRI) system, computed-tomography (CT) imaging system, positron emission tomography (PET) imaging system, among others. Further, the various embodiments may be implemented in non-medical imaging systems, for example, non-destructive testing systems such as ultrasound weld testing systems or airport baggage scanning systems.

It should be noted that the various embodiments may be implemented in hardware, software or a combination thereof. The various embodiments and/or components, for example, the modules, or components and controllers therein, also may be implemented as part of one or more computers or processors. The computer or processor may include a computing device, an input device, a display unit and an interface, for example, for accessing the Internet. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard disk drive or a removable storage drive such as a solid state drive, optical drive, and/or the like. The storage device may also be other similar means for loading computer programs or other instructions into the computer or processor.

As used herein, the term “computer” or “module” may include any processor-based or microprocessor-based system including systems using microcontrollers, reduced instruction set computers (RISC), ASICs, logic circuits, and any other circuit or processor capable of executing the functions described herein. The above examples are exemplary only, and are thus not intended to limit in any way the definition and/or meaning of the term “computer”.

The computer or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer or processor as a processing machine to perform specific operations such as the methods and processes of the various embodiments of the invention. The set of instructions may be in the form of a software program. The software may be in various forms such as system software or application software and which may be embodied as a tangible and non-transitory computer readable medium. Further, the software may be in the form of a collection of separate programs or modules, a program module within a larger program or a portion of a program module. The software also may include modular programming in the form of object-oriented programming. The processing of input data by the processing machine may be in response to operator commands, or in response to results of previous processing, or in response to a request made by another processing machine.

As used herein, the terms “software” and “firmware” are interchangeable, and include any computer program stored in memory for execution by a computer, including RAM memory, ROM memory, EPROM memory, EEPROM memory, and non-volatile RAM (NVRAM) memory. The above memory types are exemplary only, and are thus not limiting as to the types of memory usable for storage of a computer program.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the various embodiments without departing from their scope. While the dimensions and types of materials described herein are intended to define the parameters of the various embodiments, the embodiments are by no means limiting and are exemplary embodiments. Many other embodiments will be apparent to those of skill in the art upon reviewing the above description. The scope of the various embodiments should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose the various embodiments, including the best mode, and also to enable any person skilled in the art to practice the various embodiments, including making and using any devices or systems and performing any incorporated methods. The patentable scope of the various embodiments is defined by the claims, and may include other examples that occur to those skilled in the art. Such other examples are intended to be within the scope of the claims if the examples have structural elements that do not differ from the literal language of the claims, or if the examples include equivalent structural elements with insubstantial differences from the literal languages of the claims.

What is claimed is:

1. An ultrasound transducer comprising:
an acoustic layer comprising a micromachined piezoelectric composite body having a front side and an opposite back side, the micromachined piezoelectric composite body being configured to convert electrical signals into ultrasound waves to be transmitted from the front side toward a target, the micromachined piezoelectric composite body being configured to convert received ultrasound waves into electrical signals; and
a dematching layer connected to the back side of the micromachined piezoelectric composite body of the acoustic layer, the dematching layer having a higher acoustic impedance than an acoustic impedance of the acoustic layer.

2. The ultrasound transducer of claim 1, wherein the acoustic impedance of the dematching layer is at least approximately 40 MRayls.

3. The ultrasound transducer of claim 1, wherein the acoustic impedance of the acoustic layer is less than approximately 36 MRayls.

4. The ultrasound transducer of claim 1, wherein the micromachined piezoelectric composite body of the acoustic layer has at least one of an electromechanical coupling coefficient kt of at least approximately 0.7 or a piezoelectric coefficient dt of at least approximately 1500 pC/N.

5. The ultrasound transducer of claim 1, wherein the dematching layer comprises at least one of a metal, a carbide alloy, tungsten carbide, or a compound material.

6. The ultrasound transducer of claim 1, wherein the micromachined piezoelectric composite body of the acoustic layer comprises at least one of lead magnesium niobate lead titanate (PMN-PT) or lead zinc niobate-lead titanate (PZN-PT).

7. The ultrasound transducer of claim 1, wherein the micromachined piezoelectric composite body of the acoustic layer comprises piezoelectric posts that are separated from each other by voids, the voids being filled with a filler material.

8. The ultrasound transducer of claim 1, wherein the micromachined piezoelectric composite body of the acoustic layer has a single crystal structure.

9. The ultrasound transducer of claim 1, wherein the micromachined piezoelectric composite body of the acoustic layer is formed using at least one of reactive ion etching (RIE), deep reactive ion etching (DRIE), laser etching, plasma etching, wet etching, or photolithography.

10. The ultrasound transducer of claim 1, wherein the acoustic impedance of the dematching layer is between approximately 39 MRayls and approximately 121 MRayls.

11. A method for manufacturing an ultrasound transducer, the method comprising:
forming a micromachined piezoelectric composite body having a front side and an opposite back side, the micromachined piezoelectric composite body being configured to convert electrical signals into ultrasound waves to be transmitted from the front side toward a target, the micromachined piezoelectric composite body being configured to convert received ultrasound waves into electrical signals; and
connecting a dematching layer to the back side of the micromachined piezoelectric composite body, the dematching layer having a higher acoustic impedance than an acoustic impedance of the micromachined piezoelectric composite body.

12. The method of claim 11, wherein forming the micromachined piezoelectric composite body comprises etching voids into a piezoelectric substance to provide the piezoelectric substance with piezoelectric posts that are separated from each other by the voids.

13. The method of claim 11, wherein forming the micromachined piezoelectric composite body comprises forming piezoelectric posts that are separated from each other by voids, and wherein forming the micromachined piezoelectric composite body comprises filling the voids with a filler material.

14. The method of claim 11, wherein forming the micromachined piezoelectric composite body comprises filling a piezoelectric substance with a filler material.

15. The method of claim 11, wherein the acoustic impedance of the dematching layer is at least approximately 40 MRayls.

16. The method of claim 11, wherein the micromachined piezoelectric composite body has an electromechanical coupling coefficient kt of at least approximately 0.7.

17. An ultrasound transducer comprising:
a lens;
an acoustic layer comprising a micromachined piezoelectric composite body having a front side and an opposite back side, the micromachined piezoelectric composite body being configured to convert electrical signals into ultrasound waves to be transmitted from the front side toward a target, the micromachined piezoelectric composite body being configured to convert received ultrasound waves into electrical signals, the lens being connected to the front side of the micromachined piezoelectric composite body of the acoustic layer;
a dematching layer connected to the back side of the micromachined piezoelectric composite body of the acoustic layer, the dematching layer having a higher acoustic impedance than an acoustic impedance of the acoustic layer; and
a backing layer connected to the dematching layer such that the dematching layer is disposed between the backing layer and the acoustic layer.

18. The ultrasound transducer of claim 17, wherein the acoustic impedance of the dematching layer is at least approximately 40 MRayls.

19. The ultrasound transducer of claim 17, wherein the micromachined piezoelectric composite body of the acoustic layer has an electromechanical coupling coefficient kt of at least approximately 0.7.

20. The ultrasound transducer of claim 17, wherein at least one of:
the lens is indirectly connected to the front side of the micromachined piezoelectric composite body of the acoustic layer through one or more frontside matching layers disposed between the acoustic layer and the lens; or
the backing layer is indirectly connected to the dematching layer through a flex circuit flex disposed between the dematching layer and the backing layer.
